(19) United States
(12) Patent Application Publication
(10) Pub. No.: US 2026/0266888 A1
(43) Pub. Date: Sep. 10, 2026

(54) METHOD, SYSTEM, MEDIUM AND PROGRAM PRODUCT FOR TESTING STANDBY CURRENT OF SEMICONDUCTOR DEVICES

(71) Applicant: Renesas Electronics Corporation, Tokyo (JP)

(72) Inventor: Zhongqiang REN, Beijing (CN)

(21) Appl. No.: 19/559,129

(22) Filed: Mar. 6, 2026

(30) Foreign Application Priority Data
Mar. 6, 2025 (CN) 202510264547.0

(51) Int. Cl. G01R 31/26

(52) U.S. Cl. CPC G01R 31/2607

(57) ABSTRACT

A method for testing a standby current of a semiconductor device is disclosed. The semiconductor device includes a voltage regulator, a power terminal, and a power output terminal. The power terminal is connected to a power supply during testing, and the power output terminal is connected to an external capacitor during testing. The method includes: when switching from the testing in the normal operating mode to the testing in the low power mode, the change of the output voltage of the power output terminal causes the external capacitor to be charged; in the testing in the low power mode, before testing the standby current of the semiconductor device, causing a voltage source disposed between the semiconductor device and the external capacitor to apply a voltage to the power output terminal at the same level as the voltage of the power output terminal in the low power mode.

### CROSS-REFERENCE TO RELATED APPLICATIONS

The disclosure of Chinese Patent Application No. 202510264547.0 filed on Mar. 6, 2025 including the specification, drawings and abstract is incorporated herein by reference in its entirety.

### TECHNICAL FIELD

The present disclosure relates to the field of electronics, and more particularly to a method, a system, a computer-readable storage medium, and a computer program product for testing a standby current of semiconductor devices.

### BACKGROUND

Batch test of fabricated semiconductor devices is generally required. This is particularly important for yield control and cost control of semiconductor devices.

In some tests, a set of semiconductor devices, such as wafers or a plurality of chips, is mounted on a holder. In some cases, the holder is equipped with peripheral circuits that simulate the application environment of the semiconductor devices to facilitate the simulation of the semiconductor devices installed in an actual application environment and to measure the performance parameters in this situation.

For example, a capacitor capable of coupling with a terminal of a semiconductor device may be configured in a holder to simulate the actual application environment of the semiconductor devices. After powering on the semiconductor device, the capacitor coupled with the semiconductor device is used to stabilize the output voltage of the terminal of the semiconductor device. However, in the case of voltage changes in the semiconductor device, the presence of the capacitor results in a relatively long stabilization period of the output voltage of the terminal of the semiconductor device, thereby causing a problem of a relatively long test time for related test items of the semiconductor device.

### SUMMARY

In view of the above problem, embodiments of the present disclosure are directed to a method, a system, a computer-readable storage medium, and a computer program product for testing a standby current of semiconductor devices.

According to the first aspect of the present disclosure, there is provided a method for testing the standby current of a semiconductor device. The semiconductor device comprises a voltage regulator, a power source terminal, and a power output terminal. The semiconductor device has a normal operating mode and a low power mode. The power source terminal is configured to be connected to a power supply during testing, and the power output terminal is configured to be connected to an external capacitor during testing. The method includes testing the semiconductor device in the normal operating mode and testing the semiconductor device in the low power mode. When switching from the testing in the normal operating mode to the testing in the low power mode, the change of the output voltage of the power output terminal causes the external capacitor to be charged. The method further includes, in the testing in the low power mode, causing a voltage source disposed between the semiconductor device and the external capacitor to the power output terminal, at the same level as the voltage of the power output terminal in the low power mode, before testing a standby current of the semiconductor device. This causes the external capacitor to discharge, thereby suppressing the voltage fluctuation of the power output terminal.

According to the second aspect of the present disclosure, there is provided a system for testing a standby current of a semiconductor device. The semiconductor device comprises a voltage regulator, a power source terminal, and a power output terminal. The semiconductor device has a normal operating mode and a low power mode. The power source terminal is configured to be connected to a power supply during testing, and the power output terminal is configured to be connected to an external capacitor during testing. The system includes an external testing apparatus and at least one processor. The at least one processor is configured to cause the external testing apparatus to test the semiconductor device in the normal operating mode and to cause the external testing apparatus to test the semiconductor device in the low power mode. When switching from the testing in the normal operating mode to the testing in the low power mode, the change of the output voltage of the power output terminal causes the external capacitor to be charged. The at least one processor is further configured to, in the testing in the low power mode, cause the voltage source disposed between the semiconductor device and the external capacitor to apply to the power output terminal, a voltage at the same level as the voltage of the power output terminal in the low power mode, before testing the standby current of the semiconductor device. This causes the external capacitor to discharge, thereby suppressing the voltage fluctuation of the power output terminal.

According to a third aspect of the present disclosure, a computer program product comprising computer executable instructions is provided. The computer executable instructions, when executed by a processor, perform the methods according to the first aspect.

According to a fourth aspect of the present disclosure, a computer-readable storage medium storing a computer program thereon is provided. The computer program, when executed by a processor, performs the methods according to the first aspect.

It should be understood that the content described in the summary is not intended to limit the key or important features of the embodiments of the present disclosure, nor is it intended to limit the scope of the present disclosure. Other features of the present disclosure will become readily understood from the following description.

### BRIEF DESCRIPTION OF DRAWINGS

The above and other features, advantages, and aspects of various embodiments of the present disclosure will become more apparent from the following detailed description taken in conjunction with the accompanying drawings. In the drawings, the same or similar reference numbers refer to the same or similar elements, wherein:

FIG. 1A illustrates a schematic diagram of a test t of a semiconductor device in some related arts;

FIG. 1B illustrates another schematic diagram of a test of a semiconductor device in some related arts;

FIG. 2 illustrates an exemplary environment diagram for testing a standby current of a semiconductor device according to some embodiments of the present disclosure;

FIG. 3 illustrates a method for testing a standby current of a semiconductor device according to some embodiments of the present disclosure;

FIG. 4 illustrates a schematic diagram of a schematic circuit for testing a standby current of a semiconductor device according to some embodiments of the present disclosure;

FIG. 5 illustrates a schematic diagram of a capacitor for high-frequency filtering coupled in parallel with a VCL capacitor;

FIG. 6 illustrates a diagram of test items performed on a semiconductor device;

FIG. 7 illustrates a voltage change diagram of the power output terminal VCL before and after switching from a normal operating mode to a low power mode;

FIG. 8 illustrates a flowchart diagram for testing a standby current of a semiconductor device according to some embodiments of the present disclosure;

FIG. 9 illustrates a curve diagram of the measurement results of a standby current of a semiconductor device according to some embodiments of the present disclosure;

FIG. 10 illustrates a block diagram of a device capable of implementing multiple embodiments of the present disclosure.

### DETAILED DESCRIPTION

Embodiments of the present disclosure will be described in more detail below with reference to the accompanying drawings. While certain embodiments of the present disclosure are shown in the drawings, it is to be understood that the present disclosure may be implemented in various forms, and should not be construed as limited to the embodiments set forth herein. Rather, these embodiments are provided to provide a more thorough and complete understanding of the present disclosure. It should be understood that the drawings and embodiments of the present disclosure are for exemplary purposes only and are not intended to limit the scope of the present disclosure.

In the description of the embodiments of the present disclosure, the terms “including” and the like should be understood to include “including but not limited to”. The term “based on” should be understood as “based at least in part on”. The terms “one embodiment” or “the embodiment” should be understood as “at least one embodiment”. The terms “first,” “second,” and the like may refer to different or identical objects. Other explicit and implicit definitions may also be included below.

Preferred embodiments of the present disclosure will be described in more detail below with reference to the accompanying drawings. While the preferred embodiments of the present disclosure are shown in the drawings, it should be understood that the present disclosure may be implemented in various forms and should not be limited by the embodiments set forth herein. Rather, these embodiments are provided to make this disclosure more thorough and complete, and to fully convey the scope of the present disclosure.

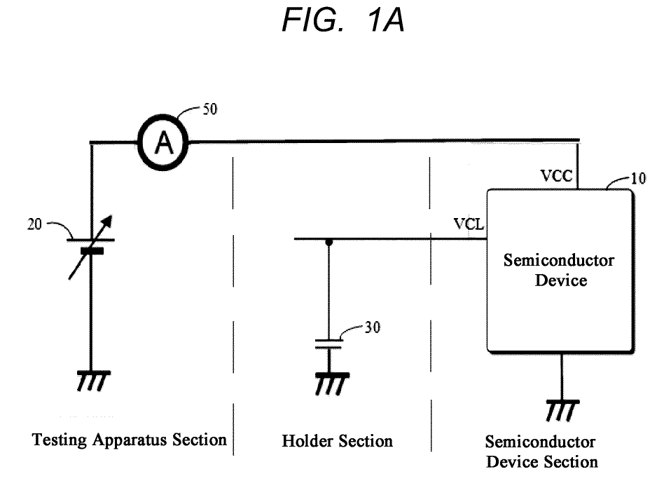

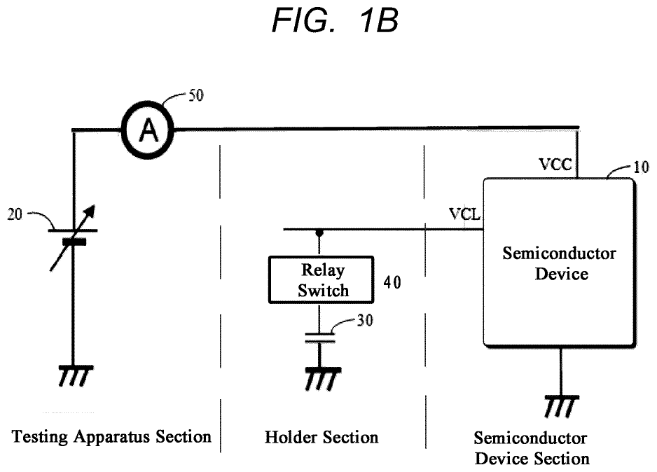

As shown in FIG. 1A, in some tests in related arts, a holder is disposed between a semiconductor device 10 and a testing apparatus including a power supply 20 and a current measurement device 50. The semiconductor device is mounted on the holder. The semiconductor device 10 is, for example, an MCU chip, etc., and has a built-in voltage regulator. The holder is, for example, a probe card or a performance board, etc. The power supply 20 is connected to a power terminal VCC of the semiconductor device 10. The current measurement device 50 measures a current flowing between the power terminal VCC of the semiconductor device 10 and the power supply 20. In some cases, the power output terminal VCL of the semiconductor device 10 will be coupled with the capacitor 30 on the holder, as shown in FIG. 1A. In this case, when performing a test of a small current such as a standby current test (for example, an IDDS static current test) on the semiconductor device 10, the mode is switched from the normal mode to the low power mode for testing. At this time, the voltage of the power output terminal VCL will change, and this change of the voltage may cause to the capacitor 30 to be charged and discharged, and the voltage of the power output terminal VCL will fluctuate, resulting in a longer time to obtain a stable current measurement result.

In order to overcome the influence of the coupling capacitance on the test duration, in some other related arts, as shown in FIG. 1B, a relay switch 40 is disposed between the power output terminal VCL and the capacitor 30. When testing the standby current, the relay switch 40 is opened, and after the test is completed, the relay switch 40 is closed. In this way, the influence of the capacitor 30 during the standby current test can be avoided, and the time to obtain a stable measurement result can be shortened. Although this can shorten the stabilization period of the output voltage of the power output terminal VCL of the semiconductor device, when multiple semiconductor devices are tested in parallel, a corresponding relay switch needs to be mounted for each external capacitor, resulting in an increase in the number of relay switches mounted in the holder. Correspondingly, the space occupied by these relay switches in the holder is increased, thereby limiting the number and space of other components mounted in the holder. In this case, the number of semiconductor devices that can be tested in parallel in one test is reduced, resulting in an increase in test cost.

In order to at least partially solve the above problems and other potential problems, various embodiments of the present disclosure provide a method, a system, a computer-readable storage medium, and a computer program product for testing a standby current of a semiconductor device. The semiconductor device includes a voltage regulator, a power terminal, and a power output terminal. The power terminal is configured to be connected to a power supply during testing, and the power output terminal is configured to be connected to an external capacitor during testing. The method includes: when switching from the testing in the normal operating mode to the testing in the low power mode, the change of the output voltage of the power output terminal causes the external capacitor to be charged, and in the testing in the low power mode, before testing the standby current of the semiconductor device, causing a voltage source disposed between the semiconductor device and the external capacitor to apply, to the power output terminal, a voltage at the same level as the voltage of the power output terminal in the low power mode, before testing a standby current of the semiconductor device. This causes the external capacitor to discharge, thereby suppressing the voltage fluctuation of the power output terminal.

By causing a voltage source disposed between the semiconductor device and the external capacitor to apply to the power output terminal, a voltage at the same level as the voltage of the power output terminal in the low power mode, before testing the standby current of the semiconductor device. In this way, even if there is no switching element between the capacitor and the terminal of the semiconductor device, the output voltage of the power output terminal of the semiconductor device can be quickly stabilized. This can shorten the test time of related test items such as the standby current of the semiconductor device, and can increase the number of test components on the holder to increase the number of semiconductor devices that can be tested simultaneously. In addition, it can shorten the total test duration for testing all semiconductor devices in a set of semiconductor devices as a whole, improve the test efficiency, and reduce the test cost.

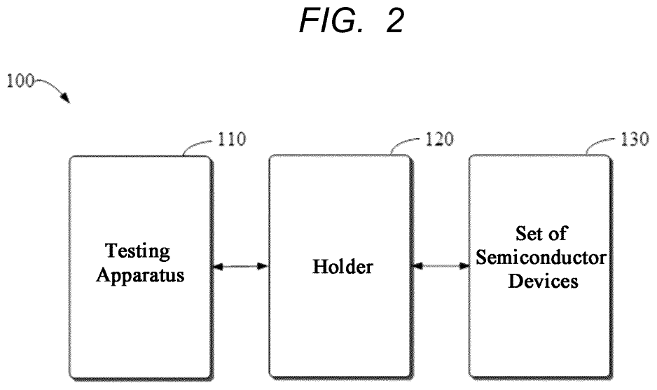

Various exemplary embodiments of the present disclosure are described below with reference to the accompanying drawings. FIG. 2 illustrates an exemplary environment diagram for testing a standby current of semiconductor devices, in accordance with some embodiments of the present disclosure. The environment 100 includes a testing apparatus 110, a holder 120, and a set of semiconductor devices 130. The testing apparatus 110 is configured to supply power to the set of semiconductor devices 130 and test performance parameters of the set of semiconductor devices such as voltage and current. In one embodiment, testing apparatus 110 includes at least one processor and at least one memory. At least one memory is coupled to the at least one processor and stores instructions for execution by the at least one processor. The instructions, when executed by the at least one processor, cause the testing apparatus to perform a test method for the set of semiconductor devices 130. The testing apparatus 110 may further include at least one voltage source and at least one switching element. It will be understood that in some embodiments, the testing apparatus 110 includes, for example, a voltage source, a switching element, and some other test circuits or components to perform various tests on the semiconductor devices. In other embodiments, testing apparatus 110 may also be implemented by a combination of a computer and a circuit testing apparatus, for example.

A holder 120 coupled between the set of semiconductor devices 130 and the testing apparatus 110 is used to clamp or carry the set of semiconductor devices 130. In addition, the holder 120 may include an external circuit device coupled with the semiconductor device, such as a capacitor. These external circuit devices may match the semiconductor device to simulate the environment in which the semiconductor device is actually operating. In one embodiment, the holder 120 may be made, for example, from a printed circuit board, probe card or performance board. The external capacitor may be soldered or otherwise placed on the printed circuit board, probe card or performance board. The set of semiconductor devices 130 may be wafers including, for example, multiple dies. Alternatively, the set of semiconductor devices 130 may also include a plurality of separate semiconductor devices, such as package chips.

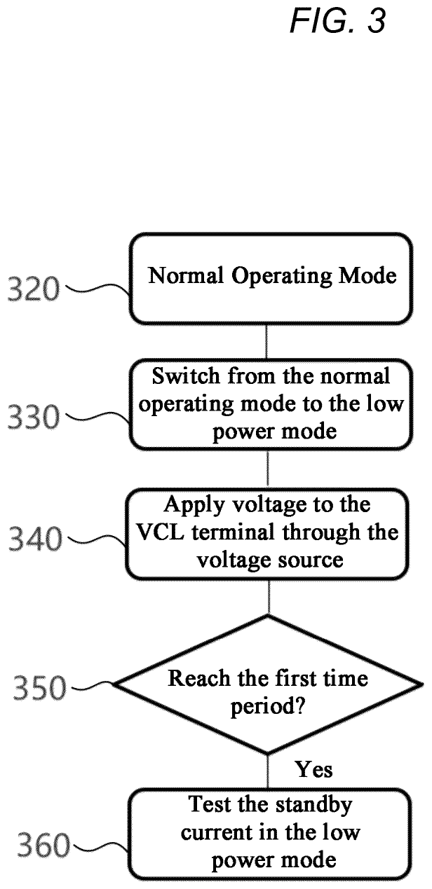

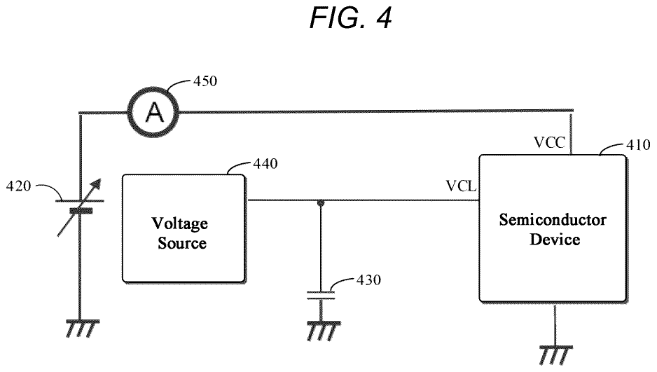

Next, a method 300 for testing a standby current of semiconductor devices with reference to FIGS. 3 and 4 is illustrated, which may be implemented, for example, by a processor of a computer not shown mounted on the testing apparatus 110. Alternatively, it may also be implemented by any suitable computer unit such as another controller, a control device, or a control module.

As shown in FIG. 3, at block 320, the semiconductor device is tested in the normal operating mode. This normal operating mode is, for example, the Normal Voltage High Current (NVHC) mode. In this mode, various tests can be performed, and the test objects include the voltages of the power terminal VCC and the power output terminal VCL of the semiconductor device, the current flowing through the power terminal VCC, and the like.

At block 330, the semiconductor device is switched from the normal operating mode to the low power mode for standby current testing. In the low power mode, the semiconductor device is in the standby mode, for example, it can be the Normal Voltage Low Current (NVLC) mode. The current in the low power mode is below a current in the normal operating mode. As mentioned above, when the operating mode changes, the voltage of the power output terminal VCL of the semiconductor device will change. The change of the voltage will cause the capacitor 430 to be charged and discharged. As an example, when the semiconductor device is switched from the normal operating mode to the low power mode, the voltage of the power output terminal VCL rises. At this time, the voltage of the power output terminal VCL is higher than that of the capacitor, so the power output terminal VCL charges the capacitor and the charge flows to the capacitor. Therefore, the voltage of the terminal VCL will fluctuate, which causes the current to be unstable.

At block 340, a voltage source is caused to apply a voltage to the power output terminal VCL at the same level as the voltage of the power output terminal VCL in the low power mode, so that the capacitor is discharged, thereby suppressing the voltage fluctuation of the power output terminal. The voltage source can be the Per pin Parametric Measurement Unit (PPMU) for DC testing of the testing apparatus or other voltage sources. Other voltage sources are, for example, the power supply circuit of the holder itself. Switching elements can also be used to control the on-off of the voltage source. By using the PPMU of the testing apparatus or other power supply circuits of the holder, there is no need to mount other voltage sources on the holder, which can save the space of the holder and reduce the cost.

In some embodiments, the voltage of the power output terminal VCL in a low power mode can be the data stored in the system in advance. The voltage of the power output terminal VCL of the semiconductor device in various operating modes can be obtained from technical manuals or design specifications. For example, the design value of the voltage in a low power mode can be obtained. According to the design manual, the voltage at the power output terminal VCL in a low power mode is 1.51V.

In other embodiments, the output voltage of the power output terminal VCL of the semiconductor device in various operating modes can be measured in advance using a voltage tester. In this regard, the method for testing semiconductor devices in some embodiments of the present disclosure also includes generating a voltage measurement signal. The voltage measurement signal causes the voltage tester to measure the voltages at the power output terminal VCL of the semiconductor device in a normal operating mode and in a low power mode. As an example, for instance, the voltage output from the power output terminal VCL in the normal operating mode, which is measured in advance by the voltage tester, is for example 1.47V, and the voltage output from the power output terminal VCL in the low power mode is for example 1.51V.

In some embodiments, the method for testing the standby current of the semiconductor device according to the present disclosure can also include generating a current measurement signal after applying voltage to the power output terminal VCL of the semiconductor device for a first period of time. In block 350, it is determined whether the voltage has been applied for the first period of time. If so, proceed to block 360.

In block 360, the current measurement device measures the current flowing between the VCC terminal and the power source in response to the received current measurement signal. For example, the current measurement signal is generated by the processor of the system. After applying a voltage at the same level as the voltage of the power output terminal in the low power mode by the voltage source for the first period of time in low power mode, the fluctuation of the current is suppressed. At this time, the measured standby current is essentially at the same level as the long-term stable standby current of the semiconductor device in low power mode. This first period of time can be the data determined in other tests and stored in the system.

In some embodiments, the voltages do not need to be applied continuously. For example, the application of voltage by a voltage source can be stopped after the second period of time. By applying voltage for the second period of time, the fluctuation of voltage is suppressed, and thereafter, even if voltage is no longer applied from the voltage source, not it will affect the current stabilization period. In some embodiments, this second period of time is shorter than the aforementioned first period of time to avoid the influence of voltage application on current measurement. This will be seen in the subsequent experimental results.

FIG. 4 illustrates a schematic diagram of a schematic circuit for testing the standby current of a semiconductor device according to some embodiments of the present disclosure. The standby current test of the semiconductor device will be further described below in conjunction with FIG. 4. The semiconductor device 410, for example, can be one of the semiconductor devices in the set of semiconductor devices 130 as shown in FIG. 2. Although described here with respect to one semiconductor device, it is understood that in some embodiments, the same and independent parallel tests can be performed simultaneously on multiple semiconductor devices in the set of semiconductor devices 130, where the steps or stages of the tests performed for each semiconductor device are the same or similar. The semiconductor device 410 has a power output terminal VCL and a power source terminal VCC coupled to the power source 420. In one embodiment, the power source 420 is mounted on the testing apparatus 110 to supply power to the semiconductor device 410. The power source 420 can vary the magnitude of the voltage applied to the power source terminal VCC of the semiconductor device 410 as needed, and in some embodiments, for example, a voltage of 5.5V may be applied.

In some embodiments, the semiconductor device 410 may, for example, be provided with a built-in voltage regulator (not shown) to switch between different operating modes. The voltage regulator is controlled by a control signal generated by an unillustrated computer unit (e.g., a processor) mounted on the testing apparatus 110 to cause the semiconductor device 410 to switch between different operating modes, in which case the power output terminal VCL of the semiconductor device 410 may be an external capacitor terminal of the internal voltage regulator. Alternatively, the operating mode switching of the semiconductor device 410 may also be implemented by controlling other components built in the semiconductor device or using other control methods.

As described above, in the normal operating mode, a primary side current of the semiconductor device 410 (i.e., a current flowing between the power source terminal of the semiconductor device 410 and the power source 420) is a relatively large current making the semiconductor device 410 operating in a normal operating mode. This primary side current may be measured, for example, using a current measurement device 350 coupled between the power source terminal VCC of the semiconductor device 410 and the power source 420. The current measurement device 350 may be mounted on the testing apparatus 110 or may be a current measurement device that is independent of the testing apparatus 110. In the low power mode, the semiconductor device 410 is in an inactive standby state, and the standby current between the power source terminal of the semiconductor device 410 and the power source 420 is a small current, for example, a few hundred nA.

The first voltage output from the power output terminal VCL in the normal operating mode of the semiconductor device 410 is different from the second voltage output from the power output terminal VCL in the low power mode. The first voltage may be higher than the second voltage, or may be below the second voltage. In some embodiments of the present disclosure, an example in which the first voltage is below the second voltage is used for description, but it is understood that this is not a limitation on the scope of the present disclosure. It should be noted that the change in operating modes of the semiconductor device is not limited to the aforementioned mode changes, but can also involve changes between other operating modes of the semiconductor device.

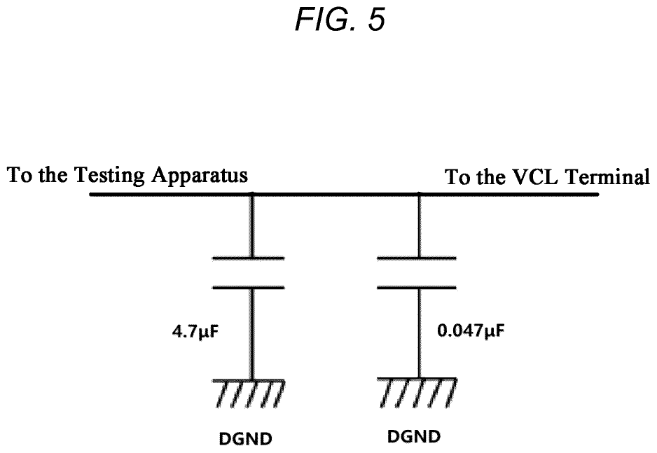

In some embodiments, the power output terminal VCL of the semiconductor device 410 is coupled to one end of the capacitor 430 in the holder 120 mounted in the testing apparatus 110, and the other end of the capacitor 430 is grounded. The capacitor 430 may stabilize the output voltage of the power output terminal VCL of the semiconductor device 410. A capacitor 330 coupled to the power output terminal VCL of the semiconductor device 410 is mounted on the holder 120 to simulate the actual application environment of the semiconductor device 410. In some embodiments, the capacitor 430 may, for example, use a 4.7 μF large capacity capacitor, but is not limited thereto. Other capacities can be used as long as the capacitor 430 can stabilize the voltage. In addition, in some embodiments, a capacitor for high frequency filtering coupled in parallel with the first capacitor is further included, as shown in FIG. 5. The capacitor for filtering may have a small capacity compared to capacitor 430 (e.g., 4.7 μF), such as 0.047 μF. In this case, the effect of the filter capacitor on the output voltage of the VCL terminal of the semiconductor device is extremely small.

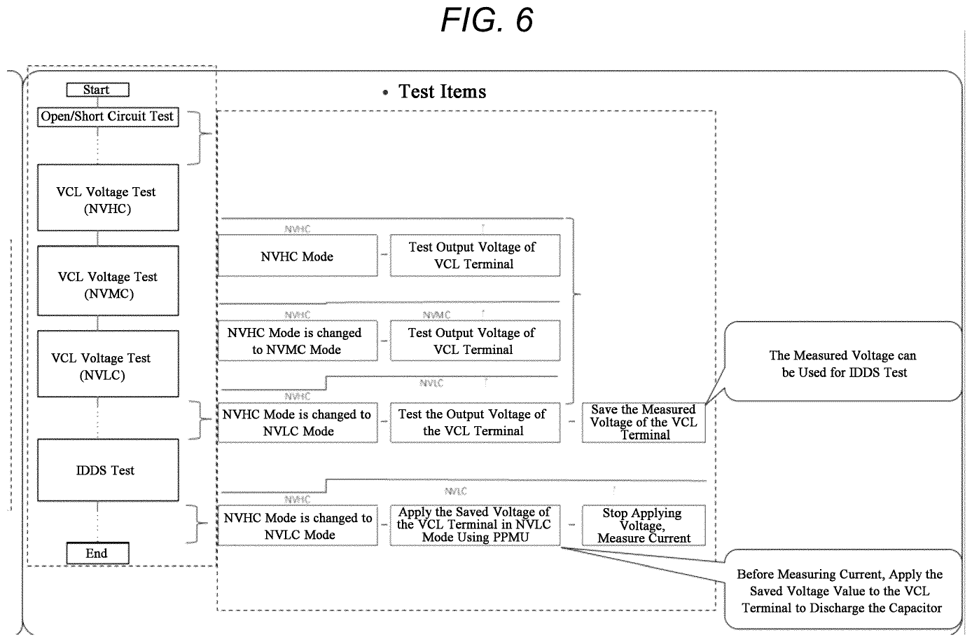

FIG. 6 shows a schematic diagram of various tests performed on the semiconductor device. As shown, the tests can include open/short circuit test, VCL high voltage test (NVHC), VCL medium voltage test (NVMC), VCL low voltage test (NVLC), IDDS current test, etc. In the NVHC test item, when the semiconductor device 410 is in the NVHC mode, the output voltage of the VCL terminal is tested. Subsequently, the NVHC mode can be changed to the NVMC mode. In the NVMC mode, the output voltage of the VCL terminal can be tested. Subsequently, during the NVLC test, a reference test can be performed. For example, the mode of the semiconductor device 410 is changed from the NVHC mode to the NVLC mode, and the steady—state output voltage of the VCL terminal is tested, and the measured voltage of the VCL terminal is saved. For example, it can be stored in the memory of the testing apparatus 110 for subsequent query. In some embodiments, in the stage of performing the IDDS current test on the semiconductor device 410, the standby current test of the semiconductor device according to some embodiments of the present disclosure can be performed, for example, referring to the standby current test procedure described above with respect to FIGS. 3 and 4. For example, when changing from the NVHC mode to the NVLC mode, the PPMU is used to apply the voltage of the VCL terminal measured and saved in the NVLC mode, and after a short period of time, the application of the voltage is stopped and the current at this time is measured. It can be understood that before measuring the current, the saved voltage value is applied to the VCL terminal according to the embodiments of the present disclosure, so that the capacitor discharges. Although the voltage of the VCL terminal is saved in the NVLC stage here, it can be understood that this is only an example and does not limit the scope of the present disclosure. In other embodiments, the default voltage of the VCL terminal in the NVLC mode can be set by, for example, the semiconductor device manufacturer or other parties, without measuring the voltage of the VCL terminal of the semiconductor device 410 in the NVLC mode.

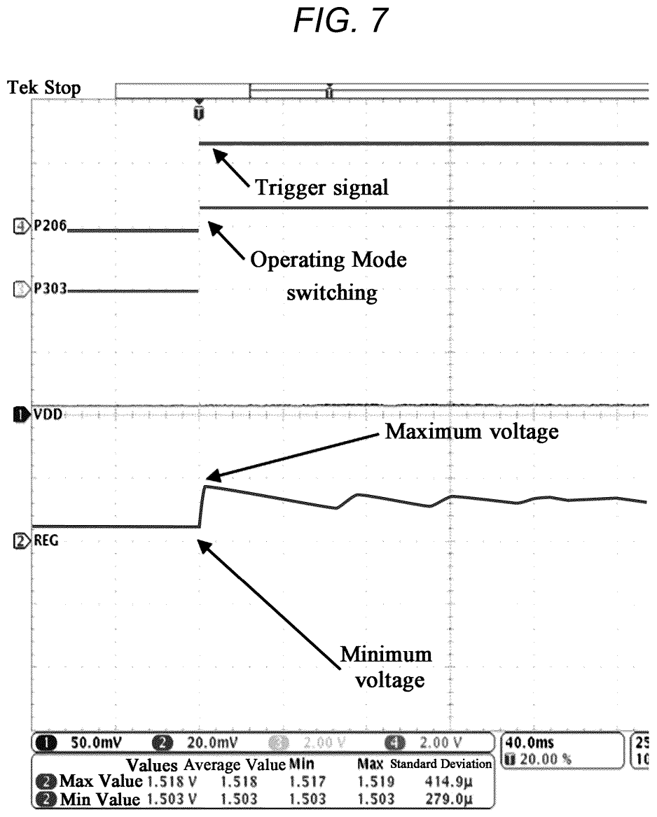

FIG. 7 shows the voltage change of the power output terminal VCL before and after the switching from the normal operating mode to the low power mode. Before the switching, the voltage of the power output terminal VCL is at a lower level, which is represented as the minimum voltage in the Figure. When the switching occurs, the voltage becomes a higher level, which is represented as the maximum voltage in the Figure. Thereafter, after several fluctuations, the voltage of the power output terminal VCL gradually becomes the stable voltage, that is, the low power mode voltage. Eventually, the voltage of the power output terminal VCL gradually becomes the low power mode voltage, and the current also gradually becomes stable.

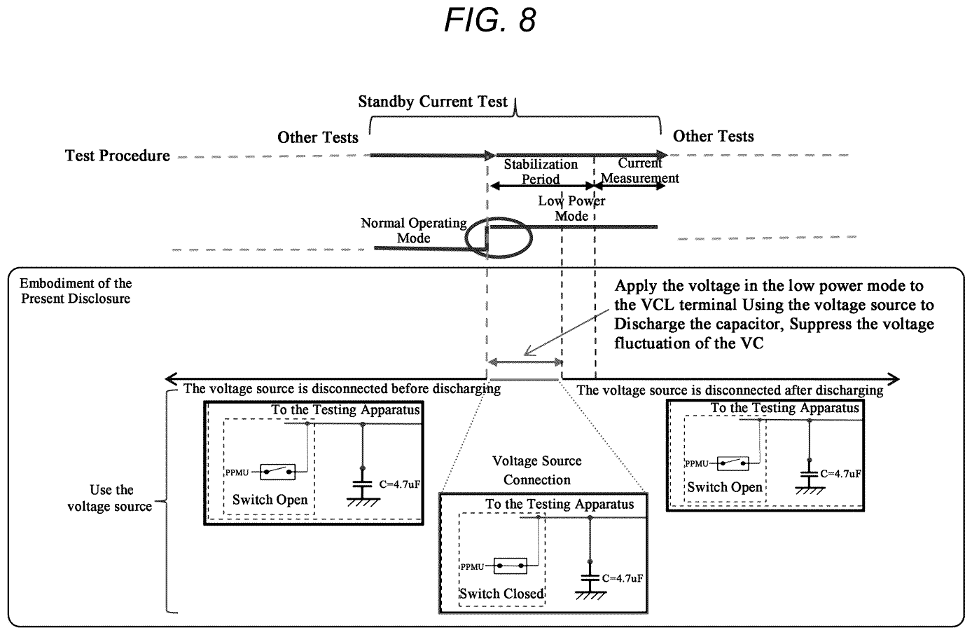

In one embodiment, as shown in FIG. 8, during the normal operating mode, the switch connected in series with the voltage source is open. At this time, the voltage source does not apply a voltage to the power output terminal VCL. When switching from the normal operating mode to the low power mode, the switch connected in series with the voltage source is closed. The voltage source starts to apply a voltage to the power output terminal VCL. When the application of this voltage reaches the second time period, the switch is opened, thereby stopping the application of the voltage. When the first time period has elapsed since the start of the application of the voltage, the current becomes stable, and at this time, the measurement of the standby current can be started.

Through the above method, when the operating mode of the semiconductor device is switched to the low power mode, a voltage source is used to apply a voltage to the power output terminal VCL of the semiconductor device at the same level as the voltage of the power output terminal VCL in the low power mode. Due to the presence of the capacitor, when switching to the low power mode, a charging and discharging circuit will be formed between the power output terminal VCL and the capacitor. At this time, the voltage of the terminal VCL will fluctuate. By applying a voltage to the power output terminal VCL at the same level as the voltage of the power output terminal VCL in the low power mode, it can help the voltage on the power output terminal VCL to become more quickly to the long-term stable voltage in the low power mode. On the other hand, the voltage of the capacitor affected by the relatively high level voltage of the power output terminal VCL in the initial switching stage becomes higher than the long-term stable voltage in the low power mode. Therefore, a charging and discharging path is formed between the capacitor and the voltage source, and the capacitor discharges to the voltage source. Therefore, compared with the situation where there is no voltage source, the influence of the capacitor on the voltage of the power output terminal VCL can be weakened. Through the above two aspects, the influence of the capacitor on the voltage of the power output terminal VCL can be weakened, so that the voltage of the power output terminal VCL can become to a stable voltage more quickly, thereby shortening the current stabilization period, effectively shortening the test time and improving the test efficiency. Compared with the technical solution using a relay switch, the test time can be shortened and the test efficiency can be improved to the same extent. In addition, the relay switch can be omitted, the space on the holder can be saved, and the overall cost can be reduced.

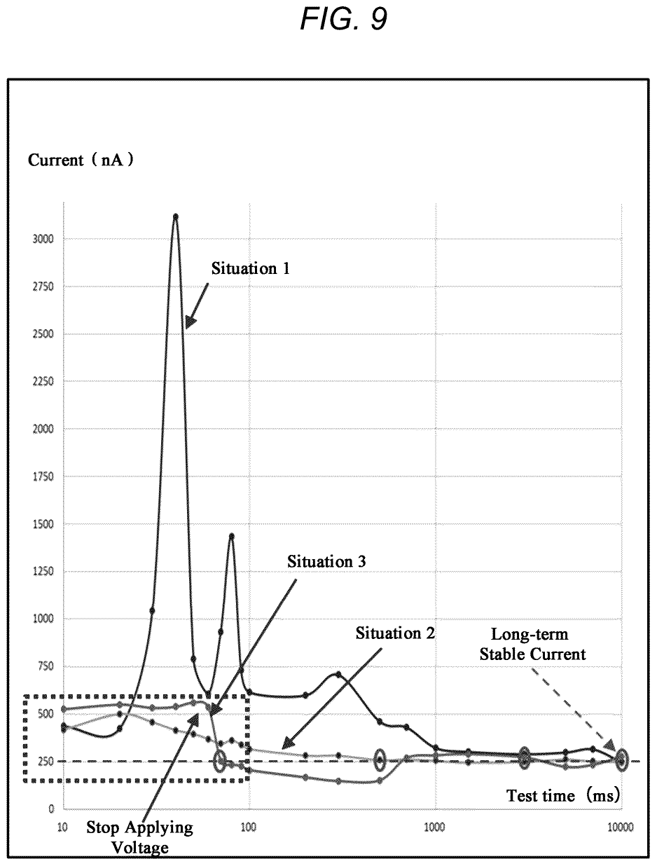

FIG. 9 shows a graph of a measurement result of the standby current of a semiconductor device according to some embodiments of the present disclosure. In FIG. 9, the measurement results of the standby current measured when the semiconductor device switches from the normal operating mode to the low power mode in the following three situations are shown:
Situation 1: No voltage source is used to apply a voltage to the VCL terminal of the semiconductor device, and no relay switch is used to disconnect the capacitor from the VCL terminal;
Situation 2: No voltage source is used to apply a voltage to the VCL terminal of the semiconductor device, but a relay switch is used to disconnect the capacitor from the VCL terminal;
Situation 3: A voltage source is used to apply a voltage to the VCL terminal of the semiconductor device at the same level as the voltage output from the VCL terminal in the low power mode, but no relay switch is used to disconnect the capacitor from the VCL terminal.

In the example shown in FIG. 9, the measured long-term stable standby current at 10000 ms is about 250 nA.

In the case of the situation 1 described above, the standby current measured after the semiconductor device switches from the normal operating mode to the low power mode is greatly fluctuated, and is nearly stabilized at about 1000 ms, but at this time, a standby current with the same level as the long-term stable current 250 nA still cannot be measured.

In the case of the above situation 2, the standby current measured after the semiconductor device switches from the normal operation mode to the low power mode fluctuates within a certain range (the range marked by the dashed box), and the standby current with the same level as the long-term stable current 250 nA can be measured between 100 ms and 1000 ms.

In the case of the above situation 3, the standby current measured after the semiconductor device switches from the normal operation mode to the low power mode fluctuates within a certain range (indicated by the dashed box), and the standby current with the same level as the long-term stable current 250 nA can be measured within 100 ms. In some embodiments, the test time that a standby current with the same level as the long-term stable current 250 nA can be measured may be set as the first time period as mentioned above.

In the situation 3, the voltage source applies a third voltage that is the same as the second voltage output from the VCL terminal in the low power mode to the VCL terminal of the semiconductor device in response to the semiconductor device switching from the normal operating mode to the low power mode. This can suppress the influence of the capacitor on the VCL terminal, so that the fluctuation of the output voltage of the VCL terminal is quickly stabilized. This can effectively shorten the test time that a standby current with the same level as the long-term stable standby current in the low power mode can be measured, and improve the test efficiency.

Compared to the situation 2 wherein a relay switch is used, the situation 3 can further to some extent shorten the test time that a standby current with the same level as the long-term stable standby current in the low power mode can be measured. In addition, since no switching element like a relay is used, the space of the holder can be avoided from being occupied, and the test cost can be saved.

In some embodiments, the method for testing a standby current of semiconductor devices further comprises generating a stop signal after applying a voltage to the VCL terminal for a second period. The voltage source stops applying the voltage to the VCL terminal in response to receiving the stop signal. In some embodiments, the second period is shorter than the first period. As shown in FIG. 9, in this embodiment, in the case of situation 3, the time point at which the application of the voltage is stopped, as indicated by the arrow, is earlier than the time point at which the current becomes stable. In this way, adverse effects on the measurement result due to the fact that the voltage source continuously applies a voltage can be effectively avoided.

Although described above with respect to the semiconductor device 410, it is to be understood that the present disclosure is not limited thereto. In some embodiments, the method for testing the semiconductor device 410 of the present disclosure can simultaneously test a plurality of semiconductor devices in a set of semiconductor devices. The test method for the other semiconductor devices is substantially the same as or similar to the test method for the semiconductor device 410 as descripted above.

In some embodiments, the operating modes of a plurality of semiconductor devices are simultaneously switched. The voltage source simultaneously applies, in response to the switching action, a voltage to the respective power output terminal VCL terminals of the multiple semiconductor devices at the same level as the voltage output from each VCL terminal in the switched operating mode. This can quickly stabilize the fluctuation of the output voltage of the VCL terminal of each semiconductor device, thereby effectively shortening the test time of test items such as measuring the standby current and improving the test efficiency.

In addition, since a relay switch and the like does not need to be coupled between each capacitor and a terminal of each semiconductor device, the space otherwise occupied by carrying these relays in the holder can be saved. Accordingly, the number of test components used for testing the semiconductor device that are mounted in the holder can be increased, so that the number of simultaneous tests of the semiconductor device can be increased. This can shorten the total test duration for testing a plurality of semiconductor devices, thereby improving the overall test efficiency and reducing the test cost.

Table 1 shows the comparison result of testing a wafer with 5446 semiconductor devices using a test system according to one embodiment. In the case where relays for the VCL capacitors are used (for example, as shown in FIG. 1B), 4 relays are used for each semiconductor device. In comparison, according to some embodiments of the present disclosure, relays for the VCL capacitors are not used. In this case, the usage amount of relays for each semiconductor device is reduced, for example, only 3 relays are used. The holder is limited in size, and the maximum number of relays that can be mounted thereon is, for example, 600. Therefore, calculated from the number of mounted relays, the number of semiconductor devices tested simultaneously in parallel at a single time in the two cases is 150 and 200 respectively. On the other hand, the number of digital channels used by a single semiconductor device is 8, and the test system has 1536 channels. Therefore, from the perspective of the number of digital channels, the number of chips tested simultaneously in parallel at a single time in both cases is 192. From these two aspects, it is determined that in the case where relays for the VCL capacitors are used, the number of simultaneous parallel tests at a single time is 150. Relatively, in the case where relays for the VCL capacitors are not used, the number of simultaneous parallel tests at a single time is 192.

TABLE 1

| | | | | | Maximum | |
|---|---|---|---|---|---|---|
| | | | Maximum | | Number of | |
| | | | Number of | | simultaneous | |
| | | Number of | simultaneous | Maximum | Tests | |
| Relays | Number of | Digital | Tests | Number of | Limited by | Final |
| for VCL | Relays per | Channels per | Limited by | Relays | Number of | Number of |
| Capacitors | Semiconductor | Semiconductor | Digital | Mounted on | Relays | simultaneous |
| Used? | Device | Device | Channels | Holder | Mounted | Tests |
| Yes | 4 | 8 | 192 | 600 | 150 | 150 |
| No | 3 | 8 | 192 | 600 | 200 | 192 |

It can be seen from the results that in the case where relays for VCL capacitors are used, the number of simultaneous tests at a single time is 150, while in the case where relays for VCL capacitors are not used, the number of simultaneous tests at a single time is 192, and the single-test efficiency is improved by 28%.

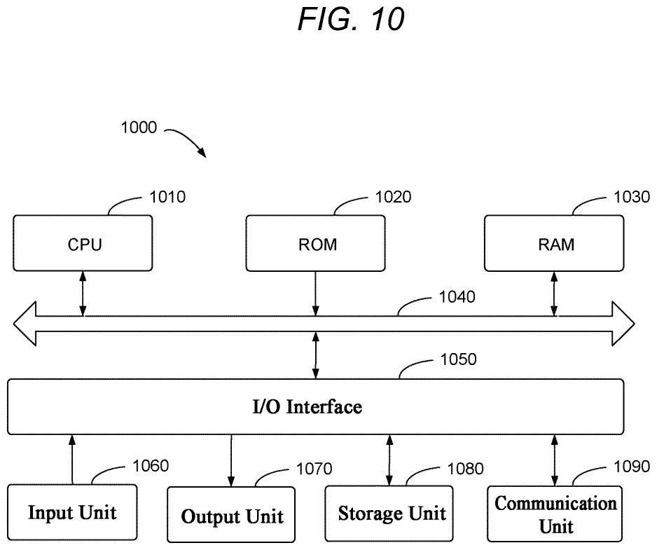

FIG. 10 illustrates a block diagram of an apparatus capable of implementing various embodiments of the present disclosure. The apparatus 1000 includes a computing unit 710 that may perform various appropriate actions and processes according to the computer program instructions stored in random access memory (RAM) and/or read only memory (ROM) 1020 or the computer program instructions loaded into RAM 1030 and/or ROM 1020 from storage unit 1080. In RAM 1030 and/or ROM 1020, various programs and data required for the operation of device 1000 may also be stored. The computing unit 1010 and the RAM 1030 and/or the ROM 1020 are connected to each other through a bus 1040. Input/output (I/O) interface 1050 is also connected to bus 1040.

The components in the device 1000 are connected to the I/O interface 1050, including: an input unit 1060, such as a keyboard, a mouse, etc.; an output unit 1070, such as various types of displays, speakers, etc.; a storage unit 1080, such as a magnetic disk, an optical disk, etc.; and a communication unit 1090, such as a network card, a modem, a wireless communication transceiver, or the like. The communication unit 1090 allows the device 1000 to exchange information/data with other equipment over a computer network such as the Internet and/or various telecommunication networks.

The computing unit 1010 may be a variety of general-purpose and/or special-purpose processing components with processing and computing capabilities. Some examples of the computing unit 1010 include, but are not limited to, a central processing unit (CPU), a graphics processing unit (GPU), various specialized artificial intelligence (AI) computing chips, various computing units running machine learning model algorithms, digital signal processors (DSPs), and any suitable processor, controller, microcontroller, or the like. The computing unit 1010 performs the various methods and processes described above, such as the method 300. In some embodiments, some or all of the computer program may be loaded and/or installed onto device 1000 via RAM and/or ROM and/or communication unit 1090. One or more steps of the method 300 described above may be performed when the computer program is loaded into the RAM and/or ROM and executed by the computing unit 1010. Alternatively, in other embodiments, the computing unit 1010 may be configured to perform the method 300 in any other suitable manner (e.g., by means of firmware).

In the foregoing embodiments, the method may be implemented in whole or in part by software, hardware, firmware, or any combination thereof, and may be implemented in whole or in part in the form of a computer program product when implemented using software. The computer program product includes one or more computer instructions, and when the computer program instructions are loaded and executed on a server or a terminal, the processes or functions described in the embodiments of this application are all or partially generated. The computer instructions may be stored in a computer-readable storage medium or transmitted from one computer-readable storage medium to another computer-readable storage medium, for example, the computer instructions may be transmitted from a website, a computer, a server, or a data center to another website, computer, server, or data center over a wired (e.g., coaxial cable, optical fiber, digital subscriber line) or wireless (e.g., infrared, wireless, microwave, etc.) manner. The computer-readable storage medium may be any available medium that can be accessed by a server or a terminal, or a data storage equipment such as a server or a data center integrated with one or more available media. The usable medium may be a magnetic medium (for example, a floppy disk, a hard disk, and a magnetic tape), or may be an optical medium (for example, a digital video disk (DVD)), or a semiconductor medium (for example, a solid state disk).

The following clauses can also be used to describe some embodiments of the present disclosure.

Clause 1. A method for testing a set of semiconductor devices, comprising:
generating a first control signal causing an operating mode of a first semiconductor device of the set of semiconductor devices to switch from a first operating mode to a second operating mode, the first semiconductor device having a first terminal coupled with a first capacitor that is independent of the first semiconductor device, a first voltage output from the first terminal in the first operating mode being different from a second voltage output from the first terminal in the second operating mode; and
in response to the first semiconductor device switching from the first operating mode to the second operating mode, generating a second control signal causing a first voltage source to apply a third voltage that is the same as the second voltage to the first terminal.

Clause 2. The method of clause 1, wherein the first semiconductor device further comprises a second terminal coupled with a first power source that is used to supply power to the first semiconductor device, the method further comprising:
after applying the third voltage to the first terminal for a first period, generating a first current measurement signal causing a first current measurement device to measure a current flowing between the second terminal and the first power source.

Clause 3. The method of clause 2, further comprising:
after applying the third voltage to the first terminal for a second period, generating a third control signal causing the first voltage source to stop applying the third voltage to the first terminal, the second period being shorter than the first period.

Clause 4. The method of any of clauses 1-3, wherein the second operating mode represents a low power mode in which the first semiconductor device is in a standby state.

Clause 5. The method of any of clauses 1-3, wherein the first semiconductor device comprises a voltage regulator configured to cause the first semiconductor device to switch between the first operating mode and the second operating mode.

Clause 6. The method of any of clauses 1-3, wherein the first voltage source is a per pin parametric measurement unit in an equipment that is used to test the set of semiconductor devices.

Clause 7. The method of any of clauses 1-3, wherein the first voltage output from the first terminal in the first operating mode is below the second voltage output from the first terminal in the second operating mode.

Clause 8. The method of any of clauses 1-3, further comprising:
before generating the first control signal, generating a voltage measurement signal causing a voltage detector to measure the first voltage output from the first terminal of the first semiconductor device in the first operating mode and the second voltage output from the first terminal in the second operating mode.

Clause 9. The method of clause 1, further comprising:
generating a fourth control signal synchronously with generating the first control signal, the fourth control signal causing an operating mode of a second semiconductor device of the set of semiconductor devices to switch from a third operating mode to a fourth operating mode, the second semiconductor device having a third terminal coupled with a second capacitor that is independent of the second semiconductor device, a fourth voltage output from the third terminal in the third operating mode being different from a fifth voltage output from the third terminal in the fourth operating mode; and
in response to the second semiconductor device switching from the third operating mode to the fourth operating mode, generating a fifth control signal causing a second voltage source to apply a sixth voltage that is the same as the fifth voltage to the third terminal.

Clause 10. The method of clause 9, wherein the second semiconductor device further comprises a fourth terminal coupled with a second power source that is used to supply power to the second semiconductor device, the method further comprising:
after applying the sixth voltage to the third terminal for a third period, generating a second current measurement signal causing a second current measurement device to measure a current flowing between the fourth terminal and the second power source.

Clause 11. The method of clause 10, further comprising:
after applying the sixth voltage to the third terminal for a fourth period, generating a sixth control signal causing the second voltage source to stop applying the sixth voltage to the third terminal, the fourth period being shorter than the third period.

Clause 12. A computer program product comprising computer executable instructions, wherein the computer executable instructions, when executed by a processor, perform the method of any of clauses 1-11.

Clause 13. A computer-readable storage medium comprising a computer program stored thereon, wherein the computer program, when executed by a processor, performs the method of any of clauses 1-11.

Clause 14. An apparatus for testing a set of semiconductor devices, comprising:
at least one processor;
at least one memory coupled to the at least one processor and storing instructions for execution by the at least one processor, the instructions, when executed by the at least one processor, causing the apparatus to perform the method of any of clauses 1-11.

Clause 15. A system for testing a set of semiconductor devices, comprising:
a first voltage source; and
at least one processor configured to:
generate a first control signal causing an operating mode of a first semiconductor device of the set of semiconductor devices to switch from a first operating mode to a second operating mode, the first semiconductor device having a first terminal coupled to a first capacitor that is independent of the first semiconductor device, a first voltage output from the first terminal in the first operating mode being different from a second voltage output from the first terminal in the second operating mode; and in response to the first semiconductor device switching from the first operating mode to the second operating mode, generating a second control signal causing the first voltage source to apply a third voltage that is the same as the second voltage to the first terminal.

Various embodiments of the present disclosure have been described above, which are exemplary, not exhaustive, and are not limited to the embodiments disclosed. Many modifications and changes will be apparent to those of ordinary skill in the art without departing from the scope and spirit of the illustrated embodiments. The selection of the terms used herein is intended to best explain the principles of the embodiments, the practical application, or improvements to the technology in the marketplace, or to enable others of ordinary skill in the art to understand the embodiments disclosed herein.

Although the present subject matter has been described in language specific to structural features and/or methodological acts, it is to be understood that the subject matter defined in the appended claims is not necessarily limited to the specific features or acts described above. Rather, the specific features and acts described above are merely exemplary forms of implementing the claims.

1. A method for testing a standby current of a semiconductor device, wherein the semiconductor device comprises a voltage regulator, a power terminal, and a power output terminal, and the semiconductor device comprises a normal operating mode and a low power mode, wherein the power terminal is configured to be connected to a power source during testing, and the power output terminal is configured to be connected to an external capacitor during the testing, the method comprising:
testing the semiconductor device in the normal operating mode and testing the semiconductor device in the low power mode, wherein when switching from the testing in the normal operating mode to the testing in the low power mode, a change of an output voltage of the power output terminal causes the external capacitor to be charged,
in the testing in the low power mode, before testing the standby current of the semiconductor device, causing a voltage source disposed between the semiconductor device and the external capacitor to apply, to the power output terminal, a voltage at the same level of a voltage of the power output terminal in the low power mode, thereby discharging the external capacitor and suppressing voltage fluctuations at the power output terminal.

2. The method of claim 1, wherein the normal operating mode is a Normal Voltage High Current (NVHC) mode, and the low power mode is a Normal Voltage Low Current (NVLC) mode, and a voltage at the power output terminal in the NVHC mode is below a voltage at the power output terminal in the NVLC mode.

3. The method of claim 1, wherein the voltage source is a Per Pin Parametric Measurement Unit (PPMU) of an external testing apparatus.

4. The method of claim 1, wherein,
after applying the voltage for a first period, generating a current measurement signal that causes a current measurement device to measure a current flowing between the power terminal and the power source.

5. The method of claim 4, wherein,
after applying the voltage for a second period, generating a stop signal that stops application of the voltage to the power output terminal, the second period being shorter than the first period.

6. The method of claim 1, further comprising testing a standby current of another semiconductor device in parallel with the testing of the standby current of the semiconductor device, wherein the testing of the standby current of another semiconductor device is independent from and identical to the testing of the standby current of the semiconductor device.

7. A system for testing a standby current of a semiconductor device,
wherein the semiconductor device comprises a voltage regulator, a power terminal, and a power output terminal, and the semiconductor device comprises a normal operating mode and a low power mode,
wherein the power terminal is configured to be connected to a power source during testing, and the power output terminal is configured to be connected to an external capacitor during the testing,
the system comprising:
an external testing apparatus; and
at least one processor configured to:
cause the external testing apparatus to test the semiconductor device in the normal operating mode and cause the external testing apparatus to test the semiconductor device in the low power mode, wherein when switching from the test procedure in the normal operating mode to the test procedure in the low power mode, a change of the output voltage of the power output terminal causes the external capacitor to charge,
wherein in the testing in the low power mode, before testing a standby current of the semiconductor device, the at least one processor causes a voltage source disposed between the semiconductor device and the external capacitor to apply, to the power output terminal, a voltage at the same level of a voltage of the power output terminal in the low power mode, thereby discharging the external capacitor and suppressing voltage fluctuations at the power output terminal.

8. The system of claim 7, wherein the normal operating mode is a Normal Voltage High Current (NVHC) mode, and the low power mode is a Normal Voltage Low Current (NVLC) mode, and a voltage at the power output terminal in the NVHC mode is below a voltage at the power output terminal in the NVLC mode.

9. The system of claim 7, wherein the voltage source is a Per Pin Parametric Measurement Unit (PPMU) of the external testing apparatus.

10. The system of claim 7, wherein,
after applying the voltage for a first period, the at least one processor generates a current measurement signal that causes the external testing apparatus to measure a current flowing between the power terminal and the power source.

11. The system of claim 10, wherein,
after applying the voltage for a second period, the at least one processor generates a stop signal that causes the external testing apparatus to stop applying the voltage to the power output terminal, the second period being shorter than the first period.

12. The system of claim 7, the system tests a standby current of another semiconductor device in parallel with the testing of a standby current of the semiconductor device, wherein the testing of a standby current of another semiconductor device is independent from and identical to the testing of a standby current of the semiconductor device.

13. A computer program product, comprising computer-executable instructions, wherein the computer-executable instructions, when executed by a processor, perform the method of claim 1.

14. A computer-readable storage medium storing a computer program, wherein the computer program, when executed by a processor, performs the method of claim 1.
